(19) United States
(12) Patent Application Publication
(10) Pub. No.: US 2025/0014857 A1
(43) Pub. Date: Jan. 9, 2025

(54) METHOD AND SYSTEM OF REDUCING CHAMBER VIBRATION

(71) Applicant: ASML Netherlands B.V., Veldhoven (NL)

(72) Inventors: Shaoqian WANG, Fremont, CA (US); Peter Paul HEMPENIUS, Eindhoven (NL); Ying LUO, San Jose, CA (US); Omar ALJANAIDEH, Santa Clara, CA (US)

(73) Assignee: ASML Netherlands B.V., Veldhoven (NL)

(21) Appl. No.: 18/709,795

(22) PCT Filed: Oct. 19, 2022
(86) PCT No.: PCT/EP2022/079037

§ 371 Date: May 13, 2024

Related U.S. Application Data
(60) Provisional application No. 63/279,658, filed on Nov. 15, 2021.

(51) Int. Cl. H01J 37/20; H01J 37/18

(52) U.S. Cl. CPC H01J 37/20; H01J 37/185; H01J 2237/0216; H01J 2237/204

(57) ABSTRACT

Systems, apparatuses, and methods for reducing vibration of a chamber may include obtaining predefined motion data associated with a transferring device stiffly coupled to a chamber; determining movement of the transferring device based on the predefined motion data before the transferring device moves; determining, based on the movement, a first force to be applied to the chamber caused by the movement; and causing a support device of the chamber to apply a second force to the chamber to counteract the first force when the transferring device moves.

### CROSS-REFERENCE TO RELATED APPLICATIONS

This application claims priority of U.S. application 63/279,658 which was filed on 15 Nov. 2021 and which is incorporated herein in its entirety by reference.

### FIELD

The description herein relates to the field of image inspection apparatus, and more particularly to reducing vibration of a vacuum chamber during sample transferring by applying feedforward control on a support device of the vacuum chamber.

### BACKGROUND

An image inspection apparatus (e.g., a charged-particle beam apparatus or an optical beam apparatus) is able to produce a two-dimensional (2D) image of a sample (e.g., a wafer substrate or simply referred to as a “wafer”) by detecting particles (e.g., photons, secondary electrons, backscattered electrons, mirror electrons, or other kinds of electrons) from a surface of a sample upon impingement by a beam (e.g., a charged-particle beam or an optical beam) generated by a source (e.g., a charged-particle source or a light source) associated with the inspection apparatus. Various image inspection apparatuses are used on semiconductor wafers in semiconductor industry for various purposes such as wafer processing (e.g., e-beam direct write lithography system), process monitoring (e.g., critical dimension scanning electron microscope (CD-SEM)), wafer inspection (e.g., e-beam inspection system), or defect analysis (e.g., defect review SEM, or say DR-SEM and Focused Ion Beam system, or say FIB).

An inspection apparatus may include a vacuum chamber for enclosing a sample holder that supports a sample to be inspected and other components for performing the inspection. Robotic arms may be used to transfer samples (e.g., wafers) between a load lock and the sample holder in the vacuum chamber. Positioning precision of the sample on the sample holder may be important to avoid physical damage to the sample and to accurately identify any defects presented in the inspection image.

### SUMMARY

Embodiments of the present disclosure provide systems and methods for reducing vibration of a chamber. In some embodiments, an apparatus may include a chamber, a transferring device stiffly coupled to the chamber, and a support device configured to support the chamber. The support device includes circuitry configured to obtain predefined motion data associated with the transferring device. The circuitry may also be configured to determine movement of the transferring device based on the predefined motion data before the transferring device moves. The circuitry may further be configured to determine, based on the movement, a first force to be applied to the chamber caused by the movement. The circuitry may further be configured to cause the support device to apply a second force to the chamber for counteracting or to counteract the first force when the transferring device moves.

In some embodiments, a non-transitory computer-readable medium may store a set of instructions that is executable by at least one processor of an apparatus. The set of instructions may cause the apparatus to perform a method. The method may include obtaining predefined motion data associated with a transferring device stiffly coupled to a chamber. The method may also include determining movement of the transferring device based on the predefined motion data before the transferring device moves. The method may further include determining, based on the movement, a first force to be applied to the chamber caused by the movement. The method may further include causing a support device of the chamber to apply a second force to the chamber for counteracting the first force when the transferring device moves.

In some embodiments, a computer-implemented method for reducing vibration of a chamber may include obtaining predefined motion data associated with a transferring device stiffly coupled to a chamber. The method may also include determining movement of the transferring device based on the predefined motion data before the transferring device moves. The method may further include determining, based on the movement, a first force to be applied to the chamber caused by the movement. The method may further include causing a support device of the chamber to apply a second force to the chamber for counteracting the first force when the transferring device moves.

In some embodiments, a support device may include circuitry configured to obtain predefined motion data from a transferring device stiffly coupled to a chamber. The circuitry may also be configured to determine movement of the transferring device based on the predefined motion data before the transferring device moves. The circuitry may further be configured to determine, based on the movement, a first force to be applied to the chamber caused by the movement. The circuitry may further be configured to cause the support device to apply a second force to the chamber for counteracting the first force when the transferring device moves.

In some embodiments, an apparatus may include a chamber, a transferring device stiffly coupled to the chamber, and a support device configured to support the chamber. The support device includes circuitry configured to obtain predefined motion data from the transferring device. The circuitry may also be configured to determine, in a feedforward control circuitry, a first force to be applied to the chamber based on the predefined motion data before the transferring device moves. The circuitry may further be configured to cause the support device to apply a second force to the chamber for counteracting the first force when the transferring device moves.

In some embodiments, a non-transitory computer-readable medium may store a set of instructions that is executable by at least one processor of an apparatus. The set of instructions may cause the apparatus to perform a method. The method may include obtaining predefined motion data from a transferring device stiffly coupled to a chamber. The method may also include determining, in a feedforward control circuitry, a first force to be applied to the chamber based on the predefined motion data before the transferring device moves. The method may further include causing the support device to apply a second force to the chamber for counteracting the first force when the transferring device moves.

In some embodiments, a computer-implemented method for reducing vibration of a chamber may include obtaining predefined motion data from a transferring device stiffly coupled to a chamber. The method may also include determining, in a feedforward control circuitry, a first force to be applied to the chamber based on the predefined motion data before the transferring device moves. The method may further include causing the support device to apply a second force to the chamber for counteracting the first force when the transferring device moves.

In some embodiments, a support device may include circuitry configured to obtain predefined motion data from a transferring device stiffly coupled to a chamber. The circuitry may also be configured to determine, in a feedforward control circuitry, a first force to be applied to the chamber based on the predefined motion data before the transferring device moves. The circuitry may further be configured to cause the support device to apply a second force to the chamber for counteracting the first force when the transferring device moves.

### BRIEF DESCRIPTION OF THE DRAWINGS

FIG. 1 is a schematic diagram illustrating an example charged-particle beam inspection (CPBI) system, consistent with some embodiments of the present disclosure.

FIG. 2 is a schematic diagram illustrating an example charged-particle beam tool, consistent with some embodiments of the present disclosure that may be a part of the example charged-particle beam inspection system of FIG. 1.

FIG. 3 is a schematic diagram illustrating an example transferring device for transferring a sample, consistent with some embodiments of the present disclosure.

FIGS. 4A-4B are graphs illustrating vibration of a chamber during transferring of a sample, consistent with some embodiments of the present disclosure.

FIG. 5A is a schematic diagram illustrating an example airmount of a chamber, consistent with some embodiments of the present disclosure.

FIG. 5B is a schematic diagram illustrating an equivalent model of a support device of a chamber, consistent with some embodiments of the present disclosure.

FIG. 6A is a schematic diagram illustrating an example process for reducing vibration of a chamber based on feedforward control, consistent with some embodiments of the present disclosure.

FIG. 6B is a schematic diagram illustrating another example process for reducing vibration of a chamber based on feedforward control and feedback control, consistent with some embodiments of the present disclosure.

FIG. 7 is a schematic diagram illustrating another example transferring device for transferring a sample, consistent with some embodiments of the present disclosure.

FIG. 8 is a flowchart illustrating an example method for reducing vibration of a chamber, consistent with some embodiments of the present disclosure.

FIG. 9 is a flowchart illustrating another example method for reducing vibration of a chamber, consistent with some embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them may be fit on the substrate. For example, an IC chip in a smartphone may be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection may be carried out using a scanning charged-particle microscope (“SCPM”). For example, a scanning charged-particle microscope may be a scanning electron microscope (SEM). A scanning charged-particle microscope may be used to image these extremely small structures, in effect, taking a “picture” of the structures of the wafer. The image may be used to determine if the structure was formed properly in the proper location. If the structure is defective, then the process may be adjusted, so the defect is less likely to recur.

The working principle of a scanning charged-particle microscope (e.g., a SEM) is similar to a camera. A camera takes a picture by receiving and recording intensity of light reflected or emitted from people or objects. A scanning charged-particle microscope takes a “picture” by receiving and recording energies or quantities of charged particles (e.g., electrons) reflected or emitted from the structures of the wafer. Typically, the structures are made on a substrate (e.g., a silicon substrate) that is placed on a platform, referred to as a stage, for imaging. Before taking such a “picture.” a charged-particle beam may be projected onto the structures, and when the charged particles are reflected or emitted (“exiting”) from the structures (e.g., from the wafer surface, from the structures underneath the wafer surface, or both), a detector of the scanning charged-particle microscope may receive and record the energies or quantities of those charged particles to generate an inspection image. To take such a “picture.” the charged-particle beam may scan through the wafer (e.g., in a line-by-line or zig-zag manner), and the detector may receive exiting charged particles coming from a region under charged particle-beam projection (referred to as a “beam spot”). The detector may receive and record exiting charged particles from each beam spot one at a time and join the information recorded for all the beam spots to generate the inspection image. Some scanning charged-particle microscopes use a single charged-particle beam (referred to as a “single-beam SCPM,” such as a single-beam SEM) to take a single “picture” to generate the inspection image, while some scanning charged-particle microscopes use multiple charged-particle beams (referred to as a “multi-beam SCPM,” such as a multi-beam SEM) to take multiple “sub-pictures” of the wafer in parallel and stitch them together to generate the inspection image. By using multiple charged-particle beams, the SEM may provide more charged-particle beams onto the structures for obtaining these multiple “sub-pictures.” resulting in more charged particles exiting from the structures. Accordingly, the detector may receive more exiting charged particles simultaneously and generate inspection images of the structures of the wafer with higher efficiency and faster speed.

For image inspection apparatuses, precisely transferring a to-be-inspected sample (e.g., a wafer) to a sample holder is important for sample protection and a higher success rate sample inspection. For example, if a sample is transferred to the sample holder with poor precision (e.g., off the center of the sample holder), an edge of the sample may hit other parts of the scanning charged-particle microscope, thereby potentially physically damaging the wafer and releasing debris into this sensitive environment. Also, if a sample is transferred to the sample holder with poor precision, an electric field applied to the sample (e.g., a static electric field for securing the sample onto the sample holder) may be warped at the edge region of the sample. Such a warped electric field may be difficult to measure and compensate, and may cause unintended defects to inspection images.

One factor impacting the precision of sample transferring is relative motion between the sample holder (e.g., a wafer stage) and a transferring device (e.g., a robotic arm). When the transferring device is stiffly coupled to a chamber (e.g., a vacuum chamber) that encloses the sample holder, the precision of sample transfer may be impacted by relative motion between the chamber and the sample holder.

However, some challenges exist in the existing methods for sample positioning. In some cases, such as in some multi-beam SCPMs, the sample holder and the chamber may not be stiffly coupled, while the transferring device is stiffly coupled to the chamber. In such cases, during sample transfer, the transferring device may move with respect to the chamber in multiple degrees of freedom. For example, the transferring device may move with respect to the chamber into any three-dimensional direction (e.g., any combination of x-, y-, or z-direction), may rotate with respect to the chamber about any axis in three-dimensional space (e.g., x-, y-, or z-axis, or any combination of them), or may move and rotate at the same time. The movement of the transferring device may apply a reaction force to the chamber. Because of the stiff coupling between the chamber and the transferring device, such a reaction force may cause significant acceleration (e.g., in a form of vibration) to the chamber. However, the sample holder may not be affected by the reaction force because the sample holder is not stiffly coupled to the chamber. As a result, the movement of the transferring device may cause significant relative motion between the chamber and the sample holder. Such significant relative motion may further cause significant inaccuracy of transferring the sample onto the sample holder. Also, for image inspection apparatuses equipped with machine material damage control (MMDC) that provides a protection mechanism, such significant relative motion may trigger the MMDC to shut down the sample holder and further terminate an inspection process, which may incur significant loss in inspection efficiency.

Typically, many existing image inspection apparatuses may adopt a strategy to reduce chamber vibration, in which the transferring device pauses and holds the sample above the sample holder until the chamber vibration attenuates below a predetermined level, then places the sample to the sample holder. In existing image inspection apparatuses, the time for waiting for the chamber vibration to attenuate may take up a majority of the time duration for sample transfer. Such a strategy may not attain both high accuracy of sample transfer and high inspection throughput. If the high accuracy of sample transfer is preferred, the transferring device may need to wait longer for the chamber vibration to attenuate further, which further lowers the inspection throughput. If the high inspection throughput is preferred, the transferring device may wait a shorter time, but the chamber vibration may be at a high level and may thus lower the accuracy of sample transfer. In addition, to assist attenuation of the chamber vibration, the movement of the transferring device may also be limited to a low speed in many existing image inspection apparatuses, which may further limit the throughput of the inspection processes.

Some existing techniques may apply feedforward or feedback control to the support device of the chamber to counteract the undesired relative motion as described above. For example, the existing techniques may use a sensor (e.g., a geophone sensor or a piezoelectric sensor) to measure the movement of the chamber and generate a feedforward signal or a feedback signal to control the support device. However, those sensor-based techniques may not effectively compensate the chamber vibration because the feedforward signal or the feedback signal may not be generated in consideration of the movement of the transferring device, and thus may not compensate the chamber vibration with sufficient effectiveness.

To enable the image inspection apparatus to transfer samples with high accuracy and high throughput, embodiments of the present disclosure provide methods, apparatuses, and systems for reducing vibration of a chamber. In some disclosed embodiments, circuitry controlling a support device (e.g., an airmount) of a chamber may obtain predefined motion data (e.g., predefined motion profile) of a transferring device (e.g., a robotic arm) that is stiffly coupled to the chamber. The circuitry may also determine movement of the transferring device based on the predefined motion data before the transferring device moves. Based on the movement, the circuitry may further determine a reaction force to be applied to the chamber caused by the movement of the transferring device. When the transferring device moves, the circuitry may cause the support device to apply (e.g., through one or more actuators) a compensation force to the chamber for counteracting the reaction force.

By applying the disclosed embodiments, some technical benefits may be achieved. The chamber vibration may be reduced to a much smaller level, and the sample transfer may achieve a higher throughput. Also, with the disclosed embodiments, the transferring device may enable more aggressive movement without incurring excessive vibrations, which may further increase the sample transfer throughput. In some cases, the improvement of the disclosed embodiments may reduce the chamber vibration by 90% and increase the sample transfer throughput by 20%. Further, with lower chamber vibration, errors in inspection images caused by sample positioning errors may be more precisely identified and determined, and thus a camera for monitoring the sample transfer process may no longer be needed, which may reduce manufacturing cost of the image inspection apparatus. Moreover, with lower chamber vibration, the sample may be positioned more precisely on a sample holder on a sample stage, and thus a gap between an edge of the sample and a rim of the sample holder may be more even. In existing image inspection apparatuses, a positioning error (represented by an offset between the center of the sample and the center of the sample holder) may be 20-80 micrometers. With the disclosed embodiments, the positioning error may be reduced to below 50 micrometers. As a result, quality of inspection image near an edge of the sample may be improved because the electrical field may be more uniformized because of the more even gap. In addition, the disclosed embodiments may improve throughput of particle per wafer pass (PWP) tests. A PWP test may be used for checking particle performance of an image inspection apparatus by checking the number of particles the apparatus contributes to the sample (e.g., a wafer). Typically, a PWP test may run 40-50 cycles, each of which may include stringent user cases and include sample transferring. Due to the improved sample transfer throughput, the disclosed embodiments may significantly improve the throughput of the PWP tests.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B. or C, or A and B, or A and C, or B and C, or A and B and C.

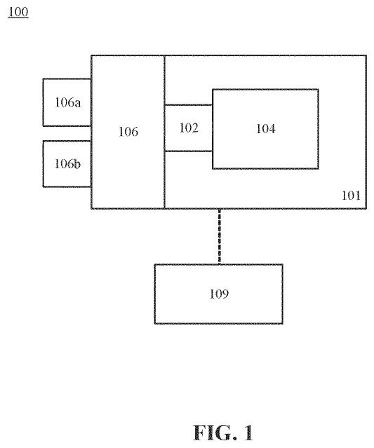

FIG. 1 illustrates an exemplary charged-particle beam inspection (CPBI) system 100 consistent with some embodiments of the present disclosure. CPBI system 100 may be used for imaging. For example, CPBI system 100 may use an electron beam for imaging. As shown in FIG. 1. CPBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to at least one of main chamber 101 or beam tool 104. Controller 109 may be a computer configured to execute various controls of CPBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

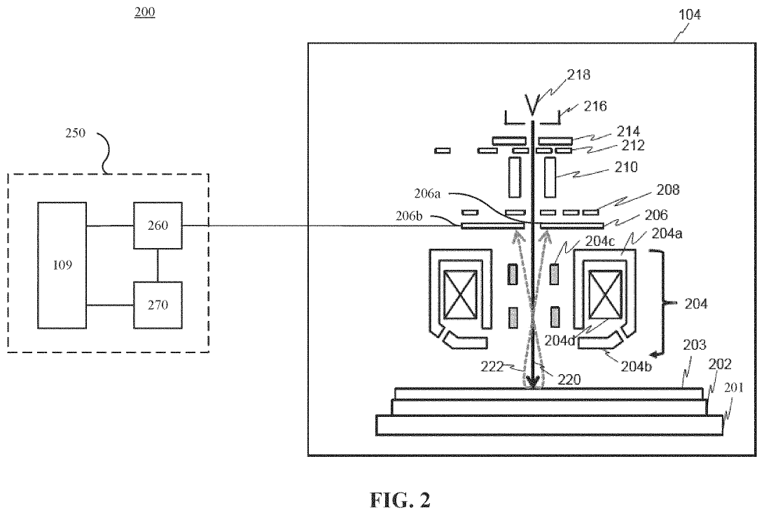

FIG. 2 illustrates an example imaging system 200 according to embodiments of the present disclosure. Beam tool 104 of FIG. 2 may be configured for use in CPBI system 100. Beam tool 104 may be a single beam apparatus or a multi-beam apparatus. As shown in FIG. 2, beam tool 104 includes a motorized sample stage 201, and a wafer holder 202 supported by motorized sample stage 201 to hold a wafer 203 to be inspected. Beam tool 104 further includes an objective lens assembly 204, a charged-particle detector 206 (which includes charged-particle sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Beam tool 104 may additionally include an Energy Dispersive X-ray Spectrometer (EDS) detector (not shown) to characterize the materials on wafer 203.

A primary charged-particle beam 220 (or simply “primary beam 220”), such as an electron beam, is emitted from cathode 218 by applying an acceleration voltage between anode 216 and cathode 218. Primary beam 220 passes through gun aperture 214 and beam limit aperture 212, both of which may determine the size of charged-particle beam entering condenser lens 210, which resides below beam limit aperture 212. Condenser lens 210 focuses primary beam 220 before the beam enters objective aperture 208 to set the size of the charged-particle beam before entering objective lens assembly 204. Deflector 204c deflects primary beam 220 to facilitate beam scanning on the wafer. For example, in a scanning process, deflector 204c may be controlled to deflect primary beam 220 sequentially onto different locations of top surface of wafer 203 at different time points, to provide data for image reconstruction for different parts of wafer 203. Moreover, deflector 204c may also be controlled to deflect primary beam 220 onto different sides of wafer 203 at a particular location, at different time points, to provide data for stereo image reconstruction of the wafer structure at that location. Further, in some embodiments, anode 216 and cathode 218 may generate multiple primary beams 220, and beam tool 104 may include a plurality of deflectors 204c to project the multiple primary beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary beam 220 may be immersed in the magnetic field and may be electrically charged, which, in turn, creates an electric field. The electric field reduces the energy of impinging primary beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary charged-particle beam 222 (or “secondary beam 222”), such as secondary electron beams, may be emitted from the part of wafer 203 upon receiving primary beam 220. Secondary beam 222 may form a beam spot on sensor surfaces 206a and 206b of charged-particle detector 206. Charged-particle detector 206 may generate a signal (e.g., a voltage, a current, or the like.) that represents an intensity of the beam spot and provide the signal to an image processing system 250. The intensity of secondary beam 222, and the resultant beam spot, may vary according to the external or internal structure of wafer 203. Moreover, as discussed above, primary beam 220 may be projected onto different locations of the top surface of the wafer or different sides of the wafer at a particular location, to generate secondary beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201 and includes beam tool 104, as discussed above. Imaging system 200 may also include an image processing system 250 that includes an image acquirer 260, storage 270, and controller 109. Image acquirer 260 may include one or more processors. For example, image acquirer 260 may include a computer, server, mainframe host, terminals, personal computer, any kind of mobile computing devices, and the like, or a combination thereof. Image acquirer 260 may connect with a detector 206 of beam tool 104 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may perform adjustments of brightness and contrast, or the like, of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, post-processed images, or other images assisting of the processing. Image acquirer 260 and storage 270 may be connected to controller 109. In some embodiments, image acquirer 260, storage 270, and controller 109 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image including a plurality of imaging areas. The single image may be stored in storage 270. The single image may be an original image that may be divided into a plurality of regions. Each of the regions may include one imaging area containing a feature of wafer 203.

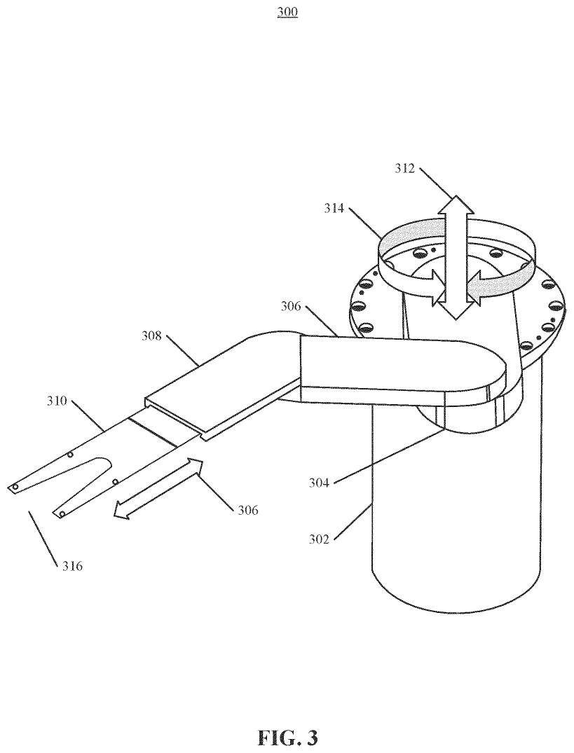

FIG. 3 is a schematic diagram illustrating an example transferring device 300 for transferring a sample, consistent with some embodiments of the present disclosure. As illustrated in FIG. 3, transferring device 300 is a robotic arm. For example, transferring device 300 may be stiffly coupled to a main chamber (e.g., main chamber 101 in FIG. 1) of an image inspection system (e.g., charged-particle beam inspection system 100 in FIG. 1). By way of example, transferring device 300 may be used for transferring or transporting a sample (e.g., a wafer) between a load/lock chamber (e.g., load/lock chamber 102 in FIG. 1) and the main chamber. A stiff coupling (also referred to as a “rigid coupling”), as used herein, refers to a connection, a link, a joint, a mount, a welding, or any type of mechanical binding that do not significantly deform under applied force, impact, or momentum. A component formed by two parts stiffly coupled may be deem as a single rigid body (e.g., with high rigidity on the two parts and their coupling). For example, if a force is applied to one part of the two parts, the force may be propagated to and impact the other part of the two parts through their stiff coupling. If one part of the two parts moves, by the third of Newton's laws of motion, a reaction force may be applied to the other part of the two parts through their stiff coupling, causing the other part to move as well.

As illustrated in FIG. 3, transferring device 300 include multiple moving parts, including a column 302 that may move up and down along a z-axis, a first arm 304 that has a first end coupled to column 302 and may rotate about the z-axis penetrating column 302, a second arm 306 that is coupled to a second end of first arm 304 and may rotate about the z-axis penetrating the second end of first arm 304, a third arm 308 that is coupled to an end of second arm 306 and may rotate about the z-axis penetrating the end of second arm 306, and an extendable section 310 that is nested in third arm 308 and may extend inward or outward along third arm 308. Extendable section 310 may include a free end 312 that may be used to hold a sample for transferring. With the multiple moving parts, transferring device 300 may have multiple degrees of freedom (DoFs) for movement, including a translational DoF 312 along a z-axis (shown as a vertical, straight double arrow), a rotational DoF 314 about the z-axis (shown as a round, horizontal double arrow), and a radial DoF 316 in a x-y plane (shown as a horizontal, straight double arrow). In some embodiments, transferring device 300 may have DoFs including translational DoFs in x-, y-, or z-axis, and rotational DoFs about the x-, y-, or z-axis. When the moving parts of transferring device 300 moves, a reaction force may be applied to the main chamber to which transferring device 300 is stiffly coupled. The reaction force may cause the main chamber to vibrate, and such vibration may be propagated to transferring device 300 through their stiff coupling. As a result, transferring device 300 may be unable to accurately transfer a sample between the load/lock chamber and the main chamber. If the image inspection apparatus is equipped with machine material damage control (MMDC), a sample stage (e.g., sample stage 201 in FIG. 2) may be shut down if the amplitude of the vibration exceeds a predetermined level (e.g., 100 micrometers), causing interruption (e.g., typically more than one hour per incident) in the inspection process.

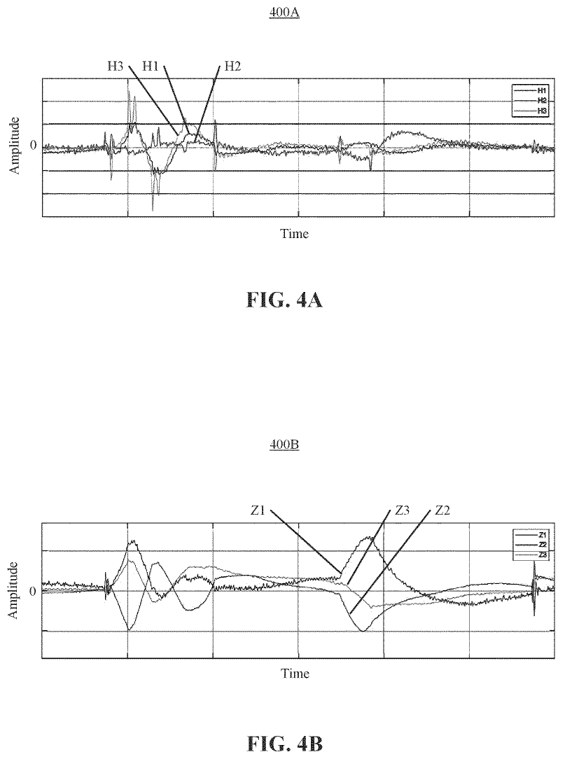

FIGS. 4A-4B are graphs illustrating vibration of a chamber during transferring of a sample, consistent with some embodiments of the present disclosure. The vibration of the chamber may be caused by movement of a transferring device (e.g., transferring device 300 in FIG. 3) stiffly coupled to the chamber. The horizontal axes of graphs in FIGS. 4A-4B represent a timeline, and the vertical axes of graphs in FIGS. 4A-4B represent an amplitude of the chamber vibration. Graph 400A in FIG. 4A illustrates chamber vibrations in three degrees of freedom H1 (e.g., representing a translational DoF in the x-axis), H2 (e.g., representing a translational DoF in the y-axis), and H3 (e.g., representing a rotational DoF about the z-axis). Graph 400B in FIG. 4B illustrates chamber vibrations in another three degrees of freedom Z1 (e.g., representing a translational DoF in the z-axis), Z2 (e.g., representing a rotational DoF about the x-axis), and Z3 (e.g., representing a rotational DoF about the y-axis). As illustrated in FIGS. 4A-4B, the chamber vibration may occur in multiple DoFs. In some typical cases, the amplitude of the chamber vibration may reach 50 micrometers in a vertical direction and 20 micrometers in a horizontal direction. Such large chamber vibration may significantly impact positional accuracy of loading a sample onto a sample stage.

Consistent with some embodiments of this disclosure, an apparatus for reducing vibration of a chamber may include the chamber and a transferring device stiffly coupled to the chamber. In some embodiments, the transferring device may have more than two (e.g., 3, 4, 5, 6, or more) degrees of freedom for the movement of the transferring device. For example, the transferring device may include a robotic arm (e.g., transferring device 300 in FIG. 3).

Consistent with some embodiments of this disclosure, the apparatus may further include a support device that supports the chamber. Feedforward signals may be used to control the support device for counteracting the vibration of the chamber caused by movement of the transferring device. Counteracting a vibration, as used herein, may refer to attenuating, canceling, negating, opposing, neutralizing, offsetting, counterbalancing, acting against, or any operation for reducing or removing the vibration. In some embodiments, the support device may include an airmount device. It should be noted that the chamber may be supported by multiple support devices (e.g., one support device at each of the four corners of a rectangular chamber).

In some embodiments, the support device may include a mass-spring-damper-actuator structure. The actuator may be used for driving or actively damping movement of the chamber. For example, the support device may include an airmount. An airmount, as used herein, refers to a soft air spring or air suspension device that utilizes compressed air inside an enclosed volume as an elastic spring.

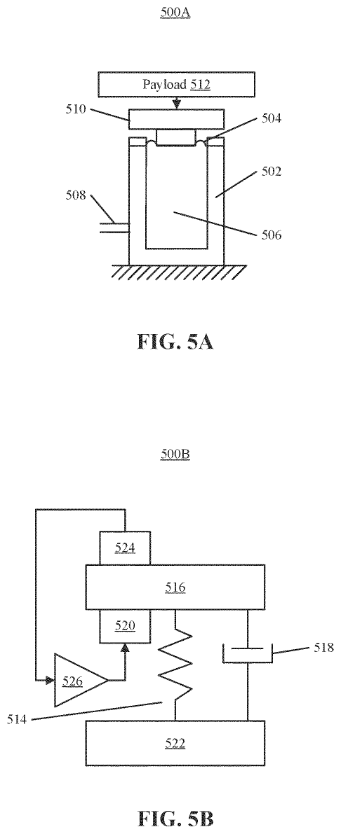

By way of example, FIG. 5A is a schematic diagram illustrating an example airmount 500A of a chamber, consistent with some embodiments of the present disclosure. Airmount 500A includes a column 502 capped by a diaphragm 504 (e.g., a rubber diaphragm). Diaphragm 504 may be movable up and down along column 502. Column 502 and diaphragm 504 encloses a volume 506. Volume 506 may be filled with compressed air that functions as an elastic spring. The compressed air in volume 506 may be filled through and controlled by a pneumatic valve 508 (e.g., a mechano-pneumatic valve or an electro-pneumatic valve). A top portion 510 may be placed on top of diaphragm 504. Top portion 510 may be used to support a payload 512 (e.g., a chamber, such as main chamber 101 of FIG. 1). In some embodiments, airmount 500A may further include one or more actuators (not shown in FIG. 5A) for driving or actively damping movement of payload 512.

Airmount 500A may be represented by an equivalent mass-spring-damper-actuator model. It should be noted that, any support device that may be represented by or equivalent to a mass-spring-damper-actuator model may be used as the support device in the disclosed embodiments, not limited to the airmount as described herein. By way of example, FIG. 5B is a schematic diagram illustrating an equivalent model of a support device 500B of a chamber, consistent with some embodiments of the present disclosure. Support device 500B is equivalent to a mass-spring-damper-actuator model. As illustrated in FIG. 5B, support device 500B includes a spring 514 (e.g., implemented as a mechanical spring or an air spring, such as the compressed air in volume 506 in FIG. 5A), a mass 516 (e.g., representing top portion 510 and payload 512 in FIG. 5A), a damper 518 (e.g., representing all components that contribute to damping), and an actuator 520 (e.g., a pneumatic valve, a linear motor, or any mechanical, electrical, or pneumatic driving device) coupled to mass 516. Spring 514 and damper 518 may both couple mass 516 to a base 522 (e.g., representing a ground or floor). Mass 516 may passively vibrate (e.g., without activating actuator 520) with respect to base 522 under influence of spring 514 and damper 518. In some embodiments, actuator 520 may drive mass 516 to perform a forced vibrate with a forcing frequency that may be different from the natural frequency of mass 516. In some embodiments, actuator 520 may actively damp the vibration of mass 516 by applying a force counteracting the movement of mass 516 with respect to base 522.

As illustrated in FIG. 5B, support device 500B further includes a feedback control loop. The feedback control loop includes a motion sensor 524 installed on mass 516 (e.g., on top portion 510 in FIG. 5A) and a controller 526 communicatively coupled to both motion sensor 524 and actuator 520. Motion sensor 524 (e.g., a proximity sensor, a position sensor, a geophone sensor, an inertia sensor, a velocity sensor, or any type of motion sensor) may be used to measure or detect a motion parameter (e.g., a position, a distance, a velocity, an acceleration, a momentum, an impulse, a vibration, or any kinematic parameter) of mass 516 and send a signal representing the motion parameter to controller 526. Controller 526 may determine a force to be applied to mass 516 based on the motion parameter, and send a driving signal representing the force to actuator 520. After receiving the driving signal, actuator 520 may apply the determined force to mass 516 to drive mass 516 to perform a forced vibration or to actively damp the vibration of mass 516.

Consistent with some embodiments of this disclosure, the support device may include circuitry to perform the following operations. The circuitry may obtain predefined motion data associated with the transferring device. The predefined motion data may be a predefined motion profile that describes movement of the transferring device. For example, the predefined motion data may be provided by manufacturer of the sample transfer device or programmed by an operator of the supporting device.

In some embodiments, the predefined motion data may represent a relationship between a spatial position of the transferring device and a time point. By way of example, the predefined motion data may include multiple pairings of positions and time points. The positions may be represented by coordinates of a reference point (e.g., free end 312 in FIG. 3) of the transferring device in multiple degrees of freedom, such as a format of (x, y, z, θₓ, θ_{y}, θ_{z}), in which (x, y, z) may represent coordinates of the reference point at x-, y-, and z-axis, respectively, and (θₓ, θ_{y}, θ_{z}) may represent rotational angles of the reference point about the x-, y-, and z-axis, respectively. In some embodiments, the time points may represent future timestamps (e.g., before the transferring device moves). For example, the pairings of positions and time points may be represented by Table 1:

TABLE 1

| Position | Time Point |
|---|---|
| (x₀, y₀, z₀, θₓ₀, θ_{y0}, θ_{z0}) | t₀ |
| (x₁, y₁, z₁, θₓ₁, θ_{y1}, θ_{z1}) | t₁ |
| (x₀, y₀, z₀, θₓ₀, θ_{y0}, θ_{z0}) | t₂ |
| . . . | . . . |
| (xₙ, yₙ, zₙ, θₓₙ, θ_{yn}, θ_{zn}) | tₙ |

In Table 1, if the time point to represents a current time, time points t₁, t₁, . . . , tₙ may represent future time stamps. In such a case, Table 1 may describe future movement (e.g., by predetermination or programming) of the transferring device.

Consistent with some embodiments of this disclosure, the circuitry of the support device may also determine movement of the transferring device based on the predefined motion data before the transferring device moves. For example, the movement of the transferring device may be represented by a velocity or an acceleration of a reference point (e.g., free end 312 in FIG. 3) of the transferring device. In some embodiments, to determine the movement of the transferring device, the circuitry may determine a speed of the transferring device based on a first derivative of the relationship (between the spatial position of the transferring device and the time point) with respect to time. In some embodiments, to determine the movement of the transferring device, the circuitry may determine an acceleration of the transferring device based on a second derivative of the relationship with respect to time.

By way of example, based on the pairings of positions and time points illustrated in Table 1, a velocity and an acceleration of the reference point of the transferring device may be determined. For example, the velocity of the reference point may be determined by a first derivative of the position with respect to the time point. By way of example, a velocity v₁ of the reference point at time point t₁ may be determined in accordance with Eq. (1):

$$Eq . ( 1 )$$

$${v}_{1} = ( {v}_{x 1} , {v}_{y 1} , {v}_{z 1} , {ω}_{x 1} , {ω}_{y 1} , {ω}_{z 1} ) = ( \frac{{x}_{1} - {x}_{0}}{{t}_{1} - {t}_{0}} , \frac{{y}_{1} - {y}_{0}}{{t}_{1} - {t}_{0}} , \frac{{z}_{1} - {z}_{0}}{{t}_{1} - {t}_{0}} , \frac{{θ}_{x 1} - {θ}_{x 0}}{{t}_{1} - {t}_{0}} , \frac{{θ}_{y 1} - {θ}_{y 0}}{{t}_{1} - {t}_{0}} , \frac{{θ}_{z 1} - {θ}_{z 0}}{{t}_{1} - {t}_{0}} )$$

In Eq. (1), (vₓ₁, v_{y1}, v_{z1}) represent linear velocity components of the reference point at x-, y-, and z-axis at time point t₁, respectively, and (ωₓ₁, ω_{y1}, ω_{z1}) represent angular velocity components of the reference point about the x-, y-, and z-axis at time point t₁, respectively.

By way of example, an acceleration a₂ of the reference point at time point t₂ may be determined in accordance with Eq. (2):

$$Eq . ( 2 )$$

$${a}_{2} = ( {a}_{x 2} , {a}_{y 2} , {a}_{z 2} , {α}_{x 2} , {α}_{y 2} , {α}_{z 2} ) = ( \frac{{v}_{x 2} - {v}_{x 1}}{{t}_{2} - {t}_{1}} , \frac{{v}_{y 2} - {v}_{y 1}}{{t}_{2} - {t}_{1}} , \frac{{v}_{z 2} - {v}_{z 1}}{{t}_{2} - {t}_{1}} , \frac{{ω}_{x 2} - {ω}_{x 1}}{{t}_{2} - {t}_{1}} , \frac{{ω}_{y 2} - {ω}_{y 1}}{{t}_{2} - {t}_{1}} , \frac{{ω}_{z 2} - {ω}_{z 1}}{{t}_{2} - {t}_{1}} )$$

In Eq. (2), (vₓ₁, v_{y1}, v_{z1}, ωₓ₁, ω_{y1}, ω_{z1}) represents velocity v₁ of the reference point at time point t₁, and (vₓ₂, v_{y2}, v_{z2}, ωₓ₂, ω_{y2}, ω_{z2}) represents velocity v₂ of the reference point at time point t₂. (aₓ₂, a_{y2}, a_{z2}) represent linear acceleration components of the reference point at x-, y-, and z-axis at time point t₂, respectively, and (αₓ₂, α_{y2}, α_{z2}) represents angular acceleration components of the reference point about the x-, y-, and z-axis at time point t₂, respectively.

Consistent with some embodiments of this disclosure, the circuitry of the support device may further determine, based on the movement, a first force (e.g., including a magnitude and a direction) to be applied to the chamber caused by the movement. The first force may be a reaction force to be applied to the chamber (when the transferring device moves) caused by the movement of the transferring device through the stiff coupling between the transferring device and the chamber. In some embodiments, the circuitry may determine the first force based on the acceleration of the transferring device. In some embodiments, the circuitry may determine the first force further based on other information of the transferring device, such as a mass of the transferring device, an inertia of the transferring device, a momentum of the transferring device, an angular momentum of the transferring device, or any other kinematic information of the transferring device. By way of example, the circuitry may determine the first force f₂ applied to the chamber at time point t₂ caused by the movement of the transferring device in accordance with Eq. (3):

$${f}_{2} = m \cdot {a}_{2} \qquad Eq . ( 3 )$$

In Eq. (3), m represents a mass of the transferring device. It should be noted that the movement of the transferring device and the first force may be determined in various manners and are not limited to the example embodiments described herein.

Consistent with some embodiments of this disclosure, the circuitry of the support device may further cause the support device to apply a second force to the chamber for counteracting the first force when the transferring device moves. The second force may be a compensation force for actively damping or canceling the first force. In some embodiments, the second force may be applied by an actuator (e.g., actuator 520 in FIG. 5B) of the support device. In some embodiments, magnitude of the second force may be substantially equal to (e.g., within a fluctuation range of +0.01 Newton) magnitude of the first force. In some embodiments, the direction of the second force may be substantially opposite (e.g., within a fluctuation range of +) 0.01° the direction of the first force.

Consistent with some embodiments of this disclosure, the apparatus may further include a sample stage that is enclosed by the chamber and not stiffly connected to the chamber. By way of example, the sample stage may be sample stage 201 in FIG. 2, which may be enclosed by main chamber 101 of FIG. 1. Main chamber 101 may be stiffly coupled to transferring device 300 of FIG. 3, while sample stage 201 is not stiffly connected to main chamber 101.

Consistent with some embodiments of this disclosure, the apparatus may further include a sensor coupled to the chamber. By way of example, the sensor may be motion sensor 524 of FIG. 5B. In such embodiments, the circuitry of the support device may further obtain, from the sensor, data representing the movement of the chamber, and cause the support device to apply a third force to the chamber for counteracting (e.g., by actively damping or canceling) the movement of the chamber when the transferring device moves. By way of example, the data representing the movement of the chamber may include a position, a distance, a velocity, an acceleration, a momentum, an impulse, a vibration, or any kinematic parameter of the chamber. In some embodiments, the circuitry may determine the third force based on the data representing the movement of the chamber and apply the third force in addition to the second force described herein.

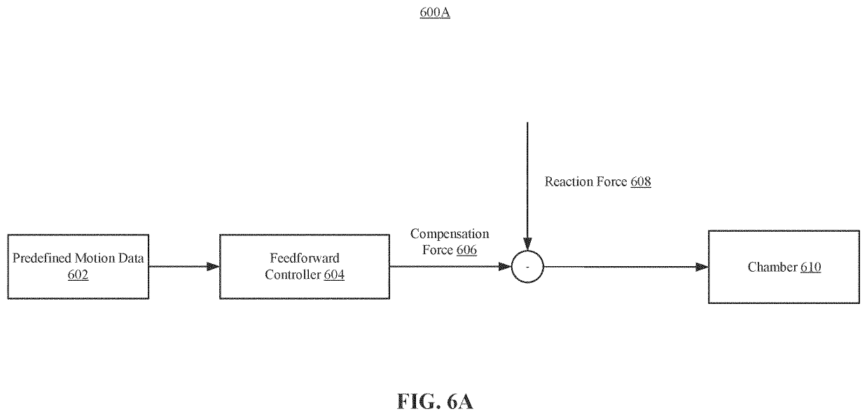

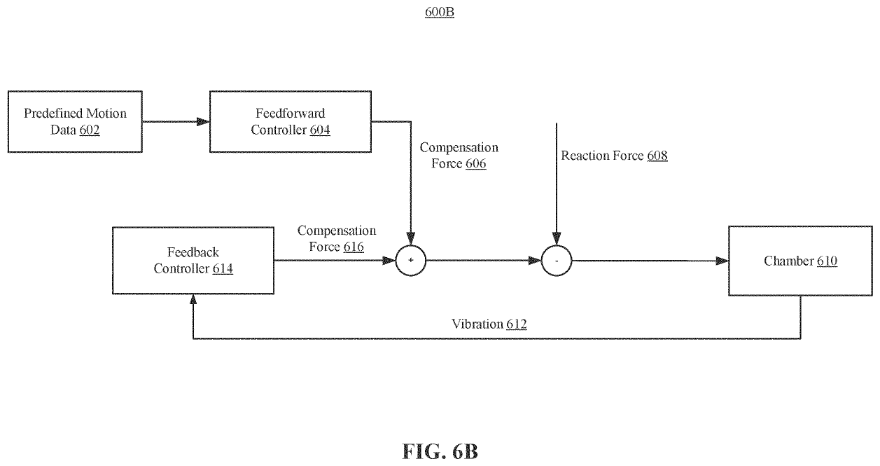

FIG. 6A is a schematic diagram illustrating an example process 600A for reducing vibration of a chamber based on feedforward control, consistent with some embodiments of the present disclosure. Process 600A may represent a feedforward control path executed by a feedforward controller coupled to a support device that supports the chamber. A feedforward control, as used herein, refers to an element or pathway within a control system that passes a controlling signal from an external source to control a load. If the control system only applies feedforward control, the control system may only respond to the controlling signal in a pre-defined way without responding to reactions of the load. The controlling signal in a feedforward control system is not error-based, and is based on prior knowledge (e.g., in form of a mathematical model) about the controlling process and disturbances to the controlling process.

As illustrated in FIG. 6A, predefined motion data 602 (e.g., a motion profile including a relationship represented by Table 1) of a transferring device (e.g., a robotic arm) stiffly coupled to a chamber 610 may be obtained by a feedforward controller 604. Before the transferring device moves, feedforward controller 604 may determine movement of the transferring device (e.g., in accordance with Eqs. (1)-(2)) based on predefined motion data 602 and a reaction force 608 to be applied to chamber 610 caused by the movement of the transferring device (e.g., in accordance with Eq. (3)). Feedforward controller 604 may further determine a compensation force 606 based on reaction force 608. For example, the direction of compensation force 606 may be substantially opposite to the direction of reaction force 608, and magnitude of compensation force 606 may be substantially equal to magnitude of reaction force 608. When the transferring device moves (e.g., in accordance with predefined motion data 602), feedforward controller 604 may cause a support device (e.g., support device 500B in FIG. 5B) supporting chamber 610 to apply compensation force 606 to chamber 610 for counteracting (e.g., by actively damping or canceling) reaction force 608.

FIG. 6B is a schematic diagram illustrating another example process 600B for reducing vibration of a chamber based on feedforward control and feedback control, consistent with some embodiments of the present disclosure. Process 600B may include a feedforward control path executed by a feedforward controller coupled to a support device that supports the chamber and include a feedback control loop executed by a feedback controller coupled to the support device. A feedback control, as used herein, refers to an element or pathway within a control system that passes a controlling signal from a load to control the load. If the control system applies feedback control, the control system may respond to reactions of the load.

As illustrated in FIG. 6B, predefined motion data 602 (e.g., a motion profile including a relationship represented by Table 1) of a transferring device (e.g., a robotic arm) stiffly coupled to a chamber 610 may be obtained by a feedforward controller 604. Before the transferring device moves, feedforward controller 604 may determine movement of the transferring device (e.g., in accordance with Eqs. (1)-(2)) based on predefined motion data 602 and a reaction force 608 to be applied to chamber 610 caused by the movement of the transferring device (e.g., in accordance with Eq. (3)). Feedforward controller 604 may further determine a compensation force 606 based on reaction force 608. For example, the direction of compensation force 606 may be substantially opposite to the direction of reaction force 608, and magnitude of compensation force 606 may be substantially equal to magnitude of reaction force 608. When the transferring device moves (e.g., in accordance with predefined motion data 602), feedforward controller 604 may cause a support device (e.g., support device 500B in FIG. 5B) supporting chamber 610 to apply compensation force 606 to chamber 610 for counteracting (e.g., by actively damping or canceling) reaction force 608.

Further, after chamber 610 moves, vibration 612 of chamber 610 may be measured or detected (e.g., by motion sensor 524 of FIG. 5B), and sent to a feedback controller 614 (e.g., implemented as controller 526 of FIG. 5B). Feedback controller 614 may determine a compensation force 616 based on vibration 612 for counteracting vibration 612. For example, the direction of compensation force 616 may be substantially opposite to the direction of vibration 612, and magnitude of compensation force 612 may be set to attenuate or cancel magnitude of vibration 612. Compensation force 616 may be applied together with compensation force 606 to chamber 610 for counteracting reaction force 608 and vibration 612.

Consistent with some embodiments of this disclosure, the transferring device stiffly coupled to the chamber may include a multi-joint robotic arm. The support device may apply a compensation force to reduce vibration to be applied to the chamber caused by movement of at least one arm of the multi-joint robotic arm.

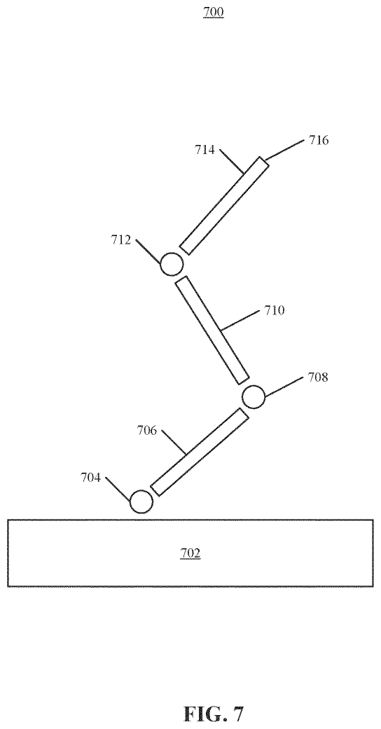

By way of example, FIG. 7 is a schematic diagram illustrating another example transferring device 700 for transferring a sample, consistent with some embodiments of the present disclosure. Transferring device 700 includes a multi-joint robotic arm that includes a base 702, a first joint 704 that includes a first actuator (not shown), a first section 706 coupled to first joint 704, a second joint 708 that includes a second actuator (not shown), a second section 710 coupled to second joint 708, a third joint 712 that includes a third actuator (not shown), and a third section 714 that is coupled to third joint 712 and includes a free end 716. Feedforward control may be applied to first joint 704, second joint 708, and third joint 712.

In some embodiments, when feedforward control is applied to first joint 704, a feedforward controller that controls first joint 704 may receive predefined motion data of first section 706, second section 710, and third section 714, and may determine a reaction force to be applied to base 702 caused by movements of first section 706, second section 710, and third section 714 before any of first section 706, second section 710, or third section 714 moves. For example, the reaction force may be a combination of a first reaction force to be applied to second section 710 caused by the movement of third section 714, a second reaction force to be applied to first section 706 caused by the movement of second section 710, and a third reaction force to be applied to base 702 caused by the movement of first section 706. The first, second, and third reaction forces may be independently determined (e.g., in accordance with Eqs. (1)-(3)) then combined by vectoral addition. Based on the reaction force, the feedforward controller may determine a compensation force. When at least one of first section 706, second section 710, or third section 714 moves, the feedforward controller may cause at least one of the first joint actuator of first joint 704, the second actuator of second joint 708, or the third actuator of joint 712 to apply the compensation force for counteracting the determined reaction force applied to base 702.

In some embodiments, when feedforward control is applied to second joint 708, base 702, first joint 704, and first section 706 may be deemed as a base structure as a whole. A feedforward controller that controls second joint 708 may receive predefined motion data of second section 710 and third section 714, and may determine a reaction force to be applied to the base structure (formed by base 702, first joint 704, and first section 706) caused by movements of second section 710 and third section 714 before any of second section 710 or third section 714 moves. For example, the reaction force may be a combination of a first reaction force to be applied to second section 710 caused by the movement of third section 714 and a second reaction force to be applied to first section 706 caused by the movement of second section 710. The first and second reaction force may be independently determined (e.g., in accordance with Eqs. (1)-(3)) then combined by vectoral addition. Based on the reaction force, the feedforward controller may determine a compensation force. When at least one of second section 710 or third section 714 moves, the feedforward controller may cause at least one of the second actuator of second joint 708 or the third actuator of joint 712 to apply the compensation force for counteracting the determined reaction force applied to the base structure (formed by base 702, first joint 704, and first section 706).

In some embodiments, when feedforward control is applied to third joint 712, base 702, first joint 704, first section 706, second joint 708, and second section 710 may be deemed as a base structure as a whole. A feedforward controller that controls third joint 712 may receive predefined motion data of third section 714, and may determine a reaction force to be applied to the base structure (formed by base 702, first joint 704, first section 706, second joint 708, and second section 710) caused by movement of third section 714 before third section 714 moves. For example, the reaction force may be a combination of a first reaction force to be applied to second section 710 caused by the movement of third section 714 and a second reaction force to be applied to first section 706 caused by the movement of second section 710. The first and second reaction force may be independently determined (e.g., in accordance with Eqs. (1)-(3)) then combined by vectoral addition. Based on the reaction force, the feedforward controller may determine a compensation force. When third section 714 moves, the feedforward controller may cause the third actuator of joint 712 to apply the compensation force for counteracting the determined reaction force applied to the base structure (formed by base 702, first joint 704, first section 706, second joint 708, and second section 710).

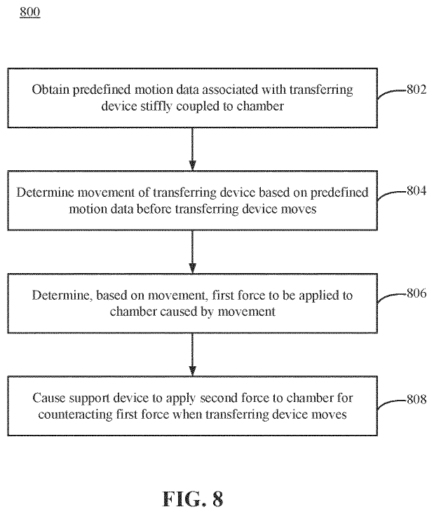

FIG. 8 is a flowchart illustrating an example method 800 for reducing vibration of a chamber, consistent with some embodiments of the present disclosure. Method 800 includes steps 802-808. Method 800 may be performed by circuitry (e.g., a controller) controlling a support device of the chamber. In some embodiments, the chamber may be part of a charged-particle inspection apparatus. The controller may be programmed to implement method 800.

At step 802, the controller may obtain predefined motion data (e.g., a motion profile) associated with a transferring device stiffly coupled to the chamber. The controller may control a support device of the chamber. In some embodiments, the support device may include an airmount device (e.g., support device 500B in FIG. 5B). In some embodiments, the transferring device may have more than two degrees of freedom for the movement. For example, the transferring device may include a robotic arm (e.g., transferring device 300 in FIG. 3). As another example, the transferring device may include a multi-joint robotic arm (e.g., transferring device 700 in FIG. 7). In some embodiments, the predefined motion data may include a relationship between a spatial position of the transferring device and a time point. For example, such a relationship may be illustrated and described in association with Table 1.

At step 804, the controller may determine movement of the transferring device based on the predefined motion data before the transferring device moves. In some embodiments, to determine the movement of the transferring device, the controller may determine a speed of the transferring device based on a first derivative of the relationship with respect to time (e.g., in accordance with Eq (1)). In some embodiments, to determine the movement of the transferring device, the controller may determine an acceleration of the transferring device based on a second derivative of the relationship with respect to time (e.g., in accordance with Eq (2)).

At step 806, the controller may determine, based on the movement, a first force (e.g., reaction force 608 in FIGS. 6A-6B) to be applied to the chamber caused by the movement. In some embodiments, the controller may determine the first force based on the acceleration of the transferring device (e.g., in accordance with Eq (3)).

At step 808, the controller may cause the support device to apply a second force (e.g., compensation force 606 in FIGS. 6A-6B) to the chamber for counteracting the first force when the transferring device moves. In some embodiments, magnitude of the second force is substantially equal to magnitude of the first force.

Consistent with some embodiments of this disclosure, besides steps 802-808, the controller may further obtain, from a sensor (e.g., sensor 524 in FIG. 5B) coupled to the chamber, data representing the movement (e.g., vibration 612 in FIG. 6B) of the chamber. Based on the data, the controller may then cause the support device to apply a third force (e.g., compensation force 616 in FIG. 6B) to the chamber for counteracting the movement of the chamber when the transferring device moves.

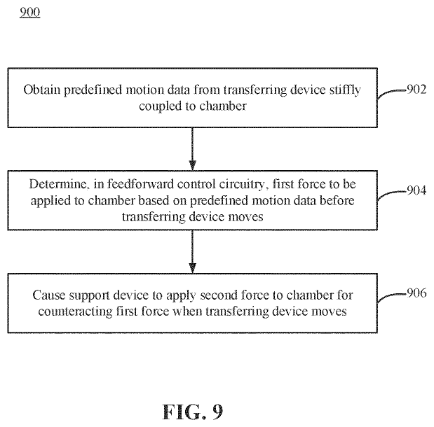

FIG. 9 is a flowchart illustrating another example method 900 for reducing vibration of a chamber, consistent with some embodiments of the present disclosure. Method 900 includes steps 902-906. Method 900 may be performed by circuitry (e.g., a controller) controlling a support device of the chamber. In some embodiments, the chamber may be part of a charged-particle inspection apparatus. The controller may be programmed to implement method 900.

At step 902, the controller may obtain predefined motion data (e.g., a motion profile) from a transferring device stiffly coupled to the chamber. The controller may control a support device of the chamber. In some embodiments, the support device may include an airmount device (e.g., support device 500B in FIG. 5B). In some embodiments, the transferring device may have more than two degrees of freedom for the movement. For example, the transferring device may include a robotic arm (e.g., transferring device 300 in FIG. 3). As another example, the transferring device may include a multi-joint robotic arm (e.g., transferring device 700 in FIG. 7). In some embodiments, the predefined motion data may include a relationship between a spatial position of the transferring device and a time point. For example, such a relationship may be illustrated and described in association with Table 1.

At step 904, the controller may determine, in a feedforward control circuitry (e.g., feedforward controller 604 in FIGS. 6A-6B), a first force (e.g., reaction force 608 in FIGS. 6A-6B) to be applied to the chamber based on the predefined motion data before the transferring device moves. In some embodiments, to determine the first force in the feedforward control circuitry, the controller may determine, in the feedforward control circuitry, movement of the transferring device based on the predefined motion data. The controller may then determine, based on the movement, the first force to be applied to the chamber caused by the movement before the transferring device moves.

In some embodiments, to determine the movement of the transferring device, the controller may determine a speed of the transferring device based on a first derivative of the relationship with respect to time (e.g., in accordance with Eq (1)). In some embodiments, to determine the movement of the transferring device, the controller may determine an acceleration of the transferring device based on a second derivative of the relationship with respect to time (e.g., in accordance with Eq (2)). In some embodiments, the controller may determine the first force based on the acceleration of the transferring device (e.g., in accordance with Eq (3)).

At step 906, the controller may cause the support device to apply a second force (e.g., compensation force 606 in FIGS. 6A-6B) to the chamber for counteracting the first force when the transferring device moves. In some embodiments, magnitude of the second force is substantially equal to magnitude of the first force.

Consistent with some embodiments of this disclosure, besides steps 902-906, the controller may further obtain, from a sensor (e.g., sensor 524 in FIG. 5B) coupled to the chamber, data representing the movement (e.g., vibration 612 in FIG. 6B) of the chamber. Based on the data, the controller may then cause, in a feedback control circuitry (e.g., feedback controller 614 in FIG. 6B), the support device to apply a third force (e.g., compensation force 616 in FIG. 6B) to the chamber for counteracting the movement of the chamber when the transferring device moves.

A non-transitory computer readable medium may be provided that stores instructions for a processor (for example, processor of controller 109 of FIG. 1) to carry out chamber vibration reduction (e.g., method 800 in FIG. 8), data processing, database management, graphical display, operations of an image inspection apparatus or another imaging device, detecting a defect on a sample, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The embodiments can further be described using the following clauses:

1. An apparatus, the apparatus comprising:
a chamber;
a transferring device stiffly coupled to the chamber; and
a support device configured to support the chamber, the support device comprising circuitry configured to:
obtain predefined motion data associated with the transferring device;
determine movement of the transferring device based on the predefined motion data before the transferring device moves;
determine, based on the movement, a first force to be applied to the chamber caused by the movement; and
cause the support device to apply a second force to the chamber to counteract the first force when the transferring device moves.
   2. The apparatus of clause 1, wherein the support device comprises an airmount device.
   3. The apparatus of any of clauses 1-2, wherein the transferring device is configured to have more than two degrees of freedom for the movement.
   4. The apparatus of any of clauses 1-3, wherein the transferring device comprises a robotic arm.
   5. The apparatus of any of clauses 1-4, wherein the transferring device comprises a multi-joint robotic arm.
   6. The apparatus of any of clauses 1-5, wherein the predefined motion data represents a relationship between a spatial position of the transferring device and a time point.
   7. The apparatus of clause 6, wherein the circuitry configured to determine the movement of the transferring device based on the predefined motion data before the transferring device moves is further configured to:
determine a speed of the transferring device based on a first derivative of the relationship with respect to time; or
determine an acceleration of the transferring device based on a second derivative of the relationship with respect to time.
   8. The apparatus of clause 7, the circuitry configured to determine, based on the movement, the first force to be applied to the chamber caused by the movement is further configured to: determine the first force based on the acceleration of the transferring device.
   9. The apparatus of any of clauses 1-8, wherein magnitude of the second force is substantially equal to magnitude of the first force.
   10. The apparatus of any of clauses 1-9, further comprising a sample stage configured to be enclosed by the chamber and not stiffly connected to the chamber.
   11. The apparatus of any of clauses 1-10, further comprising a sensor coupled to the chamber, wherein the support device comprises circuitry further configured to:
obtain, from the sensor, data representing the movement of the chamber; and
cause, based on the data, the support device to apply a third force to the chamber to counteract the movement of the chamber when the transferring device moves.
   12. A non-transitory computer-readable medium that stores a set of instructions that is executable by at least one processor of an apparatus to cause the apparatus to perform a method, the method comprising:
obtaining predefined motion data associated with a transferring device stiffly coupled to a chamber;
determining movement of the transferring device based on the predefined motion data before the transferring device moves;
determining, based on the movement, a first force to be applied to the chamber caused by the movement; and
causing a support device of the chamber to apply a second force to the chamber to counteract the first force when the transferring device moves.
   13. The non-transitory computer-readable medium of clause 12, wherein the support device comprises an airmount device.
   14. The non-transitory computer-readable medium of any of clauses 12-13, wherein the transferring device is configured to have more than two degrees of freedom for the movement.
   15. The non-transitory computer-readable medium of any of clauses 12-14, wherein the transferring device comprises a robotic arm.
   16. The non-transitory computer-readable medium of any of clauses 12-15, wherein the transferring device comprises a multi-joint robotic arm.
   17. The non-transitory computer-readable medium of any of clauses 12-16, wherein the predefined motion data comprises a relationship between a spatial position of the transferring device and a time point.
   18. The non-transitory computer-readable medium of clause 17, wherein determining the movement of the transferring device based on the predefined motion data before the transferring device moves comprises:
determining a speed of the transferring device based on a first derivative of the relationship with respect to time; or
determining an acceleration of the transferring device based on a second derivative of the relationship with respect to time.
   19. The non-transitory computer-readable medium of any of clauses 12-18, wherein determining, based on the movement, the first force to be applied to the chamber caused by the movement comprises: determining the first force based on the acceleration of the transferring device.
   20. The non-transitory computer-readable medium of any of clauses 12-19, wherein magnitude of the second force is substantially equal to magnitude of the first force.
   21. The non-transitory computer-readable medium of any of clauses 12-20, wherein the method further comprises:
obtaining, from a sensor coupled to the chamber, data representing the movement of the chamber; and
causing, based on the data, the support device to apply a third force to the chamber to counteract the movement of the chamber when the transferring device moves.
   22. A computer-implemented method for reducing vibration of a chamber, the method comprising: obtaining, by circuitry controlling a support device of the chamber, predefined motion data associated with a transferring device stiffly coupled to the chamber;
determining movement of the transferring device based on the predefined motion data before the transferring device moves;
determining, based on the movement, a first force to be applied to the chamber caused by the movement; and
causing the support device to apply a second force to the chamber to counteract the first force when the transferring device moves.
   23. The computer-implemented method of clause 22, wherein the support device comprises an airmount device.
   24. The computer-implemented method of any of clauses 22-23, wherein the transferring device is configured to have more than two degrees of freedom for the movement.
   25. The computer-implemented method of any of clauses 22-24, wherein the transferring device comprises a robotic arm.
   26. The computer-implemented method of any of clauses 22-25, wherein the transferring device comprises a multi-joint robotic arm.
   27. The computer-implemented method of any of clauses 22-26, wherein the predefined motion data comprises a relationship between a spatial position of the transferring device and a time point.
   28. The computer-implemented method of any of clauses 22-27, wherein determining the movement of the transferring device based on the predefined motion data before the transferring device moves comprises:
determining a speed of the transferring device based on a first derivative of the relationship with respect to time; or
determining an acceleration of the transferring device based on a second derivative of the relationship with respect to time.
   29. The computer-implemented method of clause 27, wherein determining, based on the movement, the first force to be applied to the chamber caused by the movement comprises: determining the first force based on the acceleration of the transferring device.
   30. The computer-implemented method of any of clauses 22-29, wherein magnitude of the second force is substantially equal to magnitude of the first force.
   31. The computer-implemented method of any of clauses 22-30, further comprising:
obtaining, from a sensor coupled to the chamber, data representing the movement of the chamber; and causing, based on the data, the support device to apply a third force to the chamber to counteract the movement of the chamber when the transferring device moves.
   32. A support device comprising circuitry configured to:
obtain predefined motion data from a transferring device stiffly coupled to a chamber;
determine movement of the transferring device based on the predefined motion data before the transferring device moves;
determine, based on the movement, a first force to be applied to the chamber caused by the movement; and
cause the support device to apply a second force to the chamber to counteract the first force when the transferring device moves.
   33. The support device of clause 32, wherein the support device comprises an airmount device.
   34. The support device of any of clauses 32-33, wherein the predefined motion data represents a relationship between a spatial position of the transferring device and a time point.
   35. The support device of clause 34, wherein the circuitry configured to determine the movement of the transferring device based on the predefined motion data before the transferring device moves is further configured to:
determine a speed of the transferring device based on a first derivative of the relationship with respect to time; or
determine an acceleration of the transferring device based on a second derivative of the relationship with respect to time.
   36. The support device of clause 35, wherein the circuitry configured to determine, based on the movement, the first force to be applied to the chamber caused by the movement is further configured to:
determine the first force based on the acceleration of the transferring device.
   37. The support device of any of clauses 32-36, wherein magnitude of the second force is substantially equal to magnitude of the first force.
   38. The support device of any of clauses 32-37, further comprising circuitry configured to:
obtain, from a sensor coupled to the chamber, data representing the movement of the chamber; and
cause, based on the data, the support device to apply a third force to the chamber to counteract the movement of the chamber when the transferring device moves.
   39. An apparatus comprising:
a chamber;
a transferring device stiffly coupled to the chamber; and
a support device configured to support the chamber, the support device comprising circuitry configured to:
obtain predefined motion data from the transferring device;
determine, in a feedforward control circuitry, a first force to be applied to the chamber based on the predefined motion data before the transferring device moves; and
cause the support device to apply a second force to the chamber to counteract the first force when the transferring device moves.
   40. The apparatus of clause 39, wherein the circuitry configured to determine, in the feedforward control circuitry, the first force to be applied to the chamber based on the predefined motion data before the transferring device moves is further configured to:
determine, in the feedforward control circuitry, movement of the transferring device based on the predefined motion data; and
determine, based on the movement, the first force to be applied to the chamber caused by the movement before the transferring device moves.
   41. The apparatus of clause 40, wherein the predefined motion data represents a relationship between a spatial position of the transferring device and a time point.
   42. The apparatus of clause 41, wherein the circuitry configured to determine, in the feedforward control circuitry, movement of the transferring device based on the predefined motion data is further configured to:
determine a speed of the transferring device based on a first derivative of the relationship with respect
to time; or determine an acceleration of the transferring device based on a second derivative of the relationship with respect to time.
   43. The apparatus of clause 42, wherein the circuitry configured to determine, based on the movement, the first force to be applied to the chamber caused by the movement before the transferring device moves is further configured to:
determine the first force based on the acceleration of the transferring device.
   44. The apparatus of any of clauses 39-43, wherein the support device comprises an airmount device.
   45. The apparatus of any of clauses 39-44, wherein the transferring device is configured to have more than two degrees of freedom for the movement.
   46. The apparatus of any of clauses 39-45, wherein the transferring device comprises a robotic arm.
   47. The apparatus of any of clauses 39-46, wherein the transferring device comprises a multi-joint robotic arm.
   48. The apparatus of any of clauses 39-47, wherein magnitude of the second force is substantially equal to magnitude of the first force.
   49. The apparatus of any of clauses 39-48, further comprising a sample stage configured to be enclosed by the chamber and not stiffly connected to the chamber.
   50. The apparatus of any of clauses 39-49, further comprising a sensor coupled to the chamber, wherein the circuitry is further configured to:
obtain, from the sensor, data representing the movement of the chamber; and
cause, in a feedback control circuitry based on the data, the support device to apply a third force to the chamber to counteract the movement of the chamber when the transferring device moves.
   51. A non-transitory computer-readable medium that stores a set of instructions that is executable by at least one processor of an apparatus to cause the apparatus to perform a method, the method comprising:
obtaining predefined motion data from a transferring device stiffly coupled to a chamber;
determining, in a feedforward control circuitry, a first force to be applied to the chamber based on the predefined motion data before the transferring device moves; and
causing the support device to apply a second force to the chamber to counteract the first force when the transferring device moves.
   52. The non-transitory computer-readable medium of clause 51, wherein determining, in the feedforward control circuitry, the first force to be applied to the chamber based on the predefined motion data before the transferring device moves comprises:
determining, in the feedforward control circuitry, movement of the transferring device based on the predefined motion data; and
determining, based on the movement, the first force to be applied to the chamber caused by the movement before the transferring device moves.
   53. The non-transitory computer-readable medium of clause 52, wherein the predefined motion data represents a relationship between a spatial position of the transferring device and a time point.
   54. The non-transitory computer-readable medium of clause 53, wherein determining, in the feedforward control circuitry, movement of the transferring device based on the predefined motion data comprises:
determining a speed of the transferring device based on a first derivative of the relationship with respect to time; or
determining an acceleration of the transferring device based on a second derivative of the relationship with respect to time.
   55. The non-transitory computer-readable medium of clause 54, wherein determining, based on the movement, the first force to be applied to the chamber caused by the movement before the transferring device moves comprises:
determining the first force based on the acceleration of the transferring device.
   56. The non-transitory computer-readable medium of any of clauses 51-55, wherein the support device comprises an airmount device.
   57. The non-transitory computer-readable medium of any of clauses 51-56, wherein the transferring device is configured to have more than two degrees of freedom for the movement.
   58. The non-transitory computer-readable medium of any of clauses 51-57, wherein the transferring device comprises a robotic arm.
   59. The non-transitory computer-readable medium of any of clauses 51-58, wherein the transferring device comprises a multi-joint robotic arm.
   60. The non-transitory computer-readable medium of any of clauses 51-59, wherein magnitude of the second force is substantially equal to magnitude of the first force.
   61. The non-transitory computer-readable medium of any of clauses 51-60, wherein the set of instructions that is executable by at least one processor of the apparatus to cause the apparatus to further perform:
obtaining, from a sensor coupled to the chamber, data representing the movement of the chamber; and
causing, in a feedback control circuitry based on the data, the support device to apply a third force to the chamber to counteract the movement of the chamber when the transferring device moves.
   62. A computer-implemented method for reducing vibration of a chamber, the method comprising: obtaining predefined motion data from a transferring device stiffly coupled to a chamber;
determining, in a feedforward control circuitry, a first force to be applied to the chamber based on the predefined motion data before the transferring device moves; and
causing the support device to apply a second force to the chamber to counteract the first force when the transferring device moves.
   63. The computer-implemented method of clause 62, wherein determining, in the feedforward control circuitry, the first force to be applied to the chamber based on the predefined motion data before the transferring device moves comprises:
determining, in the feedforward control circuitry, movement of the transferring device based on the predefined motion data; and
determining, based on the movement, the first force to be applied to the chamber caused by the movement before the transferring device moves.
   64. The computer-implemented method of clause 63, wherein the predefined motion data represents a relationship between a spatial position of the transferring device and a time point.
   65. The computer-implemented method of clause 64, wherein determining, in the feedforward control circuitry, movement of the transferring device based on the predefined motion data comprises:
determining a speed of the transferring device based on a first derivative of the relationship with respect to time; or
determining an acceleration of the transferring device based on a second derivative of the relationship with respect to time.
   66. The computer-implemented method of clause 65, wherein determining, based on the movement, the first force to be applied to the chamber caused by the movement before the transferring device moves comprises:
determining the first force based on the acceleration of the transferring device.
   67. The computer-implemented method of any of clauses 62-66, wherein the support device comprises an airmount device.
   68. The computer-implemented method of any of clauses 62-67, wherein the transferring device is configured to have more than two degrees of freedom for the movement.
   69. The computer-implemented method of any of clauses 62-68, wherein the transferring device comprises a robotic arm.
   70. The computer-implemented method of any of clauses 62-69, wherein the transferring device comprises a multi-joint robotic arm.
   71. The computer-implemented method of any of clauses 62-70, wherein magnitude of the second force is substantially equal to magnitude of the first force.
   72. The computer-implemented method of any of clauses 62-71, further comprising:
obtaining, from a sensor coupled to the chamber, data representing the movement of the chamber; and
causing, in a feedback control circuitry based on the data, the support device to apply a third force to the chamber to counteract the movement of the chamber when the transferring device moves.
   73. A support device, comprising circuitry configured to:
obtain predefined motion data from a transferring device stiffly coupled to a chamber;
determine, in a feedforward control circuitry, a first force to be applied to the chamber based on the predefined motion data before the transferring device moves; and
cause the support device to apply a second force to the chamber to counteract the first force when the transferring device moves.
   74. The support device of clause 73, wherein the circuitry configured to determine, in the feedforward control circuitry, the first force to be applied to the chamber based on the predefined motion data before the transferring device moves is further configured to:
determine, in the feedforward control circuitry, movement of the transferring device based on the predefined motion data; and
determine, based on the movement, the first force to be applied to the chamber caused by the movement before the transferring device moves.
   75. The support device of clause 74, wherein the predefined motion data represents a relationship between a spatial position of the transferring device and a time point.
   76. The support device of clause 75, wherein the circuitry configured to determine, in the feedforward control circuitry, movement of the transferring device based on the predefined motion data is further configured to:
determine a speed of the transferring device based on a first derivative of the relationship with respect to time; or
determine an acceleration of the transferring device based on a second derivative of the relationship with respect to time.
   77. The support device of clause 76, wherein the circuitry configured to determine, based on the movement, the first force to be applied to the chamber caused by the movement before the transferring device moves is further configured to:
determine the first force based on the acceleration of the transferring device.
   78. The support device of any of clauses 73-77, wherein the support device comprises an airmount device.
   79. The support device of any of clauses 73-78, wherein magnitude of the second force is substantially equal to magnitude of the first force.
   80. The support device of any of clauses 73-79, further comprising circuitry configured to:
obtain, from a sensor coupled to the chamber, data representing the movement of the chamber; and
cause, based on the data, the support device to apply a third force to the chamber to counteract the movement of the chamber when the transferring device moves.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. An apparatus comprising:
a chamber;
a transferring device stiffly coupled to the chamber; and
a support device configured to support the chamber, the support device comprising circuitry configured to:
obtain predefined motion data associated with the transferring device;
determine movement of the transferring device based on the predefined motion data before the transferring device moves;
determine, based on the movement, a first force to be applied to the chamber caused by the movement; and
cause the support device to apply a second force to the chamber to counteract the first force when the transferring device moves.

2. The apparatus of claim 1, wherein the support device comprises an airmount device.

3. The apparatus of claim 1, wherein the transferring device is configured to have more than two degrees of freedom for the movement.

4. The apparatus of claim 1, wherein the transferring device comprises a robotic arm.

5. The apparatus of claim 1, wherein the transferring device comprises a multi-joint robotic arm.

6. The apparatus of claim 1, wherein the predefined motion data represents a relationship between a spatial position of the transferring device and a time point.

7. The apparatus of claim 6, wherein the circuitry configured to determine the movement of the transferring device based on the predefined motion data before the transferring device moves is further configured to:
determine a speed of the transferring device based on a first derivative of the relationship with respect to time; or
determine an acceleration of the transferring device based on a second derivative of the relationship with respect to time.

8. The apparatus of claim 7, wherein the circuitry configured to determine, based on the movement, the first force to be applied to the chamber caused by the movement is further configured to:
determine the first force based on the acceleration of the transferring device.

9. The apparatus of claim 1, wherein magnitude of the second force is substantially equal to magnitude of the first force.

10. The apparatus of claim 1, further comprising a sample stage configured to be enclosed by the chamber and not stiffly connected to the chamber.

11. The apparatus of claim 1, further comprising a sensor coupled to the chamber, wherein the support device comprises circuitry configured to:
obtain, from the sensor, data representing the movement of the chamber; and
cause, based on the data, the support device to apply a third force to the chamber to counteract the movement of the chamber when the transferring device moves.

12. A non-transitory computer-readable medium that stores a set of instructions that is executable by at least one processor of an apparatus to cause the apparatus to perform a method, the method comprising:
obtaining predefined motion data associated with a transferring device stiffly coupled to a chamber;
determining movement of the transferring device based on the predefined motion data before the transferring device moves;
determining, based on the movement, a first force to be applied to the chamber caused by the movement; and
causing a support device of the chamber to apply a second force to the chamber to counteract the first force when the transferring device moves.

13. The non-transitory computer-readable medium of claim 12, wherein the support device comprises an airmount device.

14. The non-transitory computer-readable medium of claim 12, wherein the transferring device comprises a multi-joint robotic arm.

15. The non-transitory computer-readable medium of claim 12, wherein the method further comprises:
obtaining, from a sensor coupled to the chamber, data representing the movement of the chamber; and
causing, based on the data, the support device to apply a third force to the chamber to counteract the movement of the chamber when the transferring device moves.

16. A support device comprising circuitry configured to:
obtain predefined motion data from a transferring device stiffly coupled to a chamber;
determine movement of the transferring device based on the predefined motion data before the transferring device moves;
determine, based on the movement, a first force to be applied to the chamber caused by the movement; and
cause the support device to apply a second force to the chamber to counteract the first force when the transferring device moves.

17. The support device of claim 16, wherein the support device comprises an airmount device.

18. The support device of claim 16, wherein the predefined motion data represents a relationship between a spatial position of the transferring device and a time point.

19. The support device of claim 18, wherein the circuitry configured to determine the movement of the transferring device based on the predefined motion data before the transferring device moves is further configured to:
determine a speed of the transferring device based on a first derivative of the relationship with respect to time; or
determine an acceleration of the transferring device based on a second derivative of the relationship with respect to time.

20. The support device of claim 19, wherein the circuitry configured to determine, based on the movement, the first force to be applied to the chamber caused by the movement is further configured to:
determine the first force based on the acceleration of the transferring device.
